(19) United States
(12) Patent Application Publication
(10) Pub. No.: US 2026/0348858 A1
(43) Pub. Date: Nov. 5, 2026

(54) LASER PROCESSING DEVICE, MICROSCOPE DEVICE, AND LASER PROCESSING METHOD

(71) Applicant: HAMAMATSU PHOTONICS K.K., Hamamatsu-shi, Shizuoka (JP)

(72) Inventors: Akira TAKEDA, Shizuoka (JP); Jumpei FUKUJIN, Shizuoka (JP); Daisuke OISHI, Shizuoka (JP); Jiro EBIHARA, Shizuoka (JP)

(73) Assignee: HAMAMATSU PHOTONICS K.K., Hamamatsu-shi, Shizuoka (JP)

(21) Appl. No.: 19/485,896

(22) PCT Filed: May 20, 2024
(86) PCT No.: PCT/JP2024/018549

§ 371 Date: Nov. 19, 2025

(30) Foreign Application Priority Data
May 22, 2023 (JP) 2023-084004

(51) Int. Cl. G01N 21/71

(52) U.S. Cl. CPC G01N 21/718

(57) ABSTRACT

A laser processing device includes a disposition unit on which a sample is disposed; a laser output unit for outputting laser light; a laser irradiation unit for irradiating the sample, which is disposed on the disposition unit, with the laser light output from the laser output unit; and a transmissive member that is disposed on an optical axis of the laser light between the sample disposed on the disposition unit and the laser irradiation unit, and that transmits the laser light. The laser irradiation unit includes a spatial light modulator that displays a modulation pattern, and that generates a first laser light and a second laser light from the laser light by modulating the laser light in accordance with the modulation pattern and emits the first laser light and the second laser light, a focusing unit for forming a first focal point by focusing the first laser light.

### TECHNICAL FIELD

The present disclosure relates to a laser processing device, a microscope device, and a laser processing method.

### BACKGROUND ART

Patent Literature 1 describes a laser processing method. In this method, a workpiece is held inside a vacuum container. The vacuum container is provided with a window that transmits a laser beam. Furthermore, a laser beam emitted from a laser light source transmits through the window, and is incident on the workpiece. Accordingly, an etching phenomenon called ablation occurs on a surface of the workpiece, and the surface of the workpiece is scraped away.

### CITATION LIST

### Patent Literature

Patent Literature 1: Japanese Unexamined Patent Publication No. 2002-248589

### SUMMARY OF INVENTION

### Technical Problem

There is a demand for performing ablation processing on a sample by irradiating the sample with laser light through a transmissive member such as the window of the vacuum container as in the laser processing method described in Patent Citation 1. When ablation processing is performed on the sample, particles may be generated from the sample, and may adhere to the transmissive member. When ablation processing is continued in a situation where the particles adhere to the transparent member, the transmittance of the transmissive member for the laser light decreases, and therefore, processing quality decreases or unintended absorption of the laser light in the transparent member occurs, thereby causing damage to the transmissive member, which is a risk.

An object of the present disclosure is to provide a laser processing device, a microscope device, and a laser processing method capable of suppressing a decrease in the transmittance of a transmissive member.

### Solution to Problem

A laser processing device according to the present disclosure is [1] “a laser processing device including: a disposition unit on which a sample is disposed; a laser output unit configured to output laser light; a laser irradiation unit configured to irradiate the sample, which is disposed on the disposition unit, with the laser light output from the laser output unit; and a transmissive member that is disposed on an optical axis of the laser light between the sample disposed on the disposition unit and the laser irradiation unit, and that transmits the laser light. The laser irradiation unit includes a spatial light modulator configured to display a modulation pattern, and configured to generate a first laser light and a second laser light from the laser light by modulating the laser light in accordance with the modulation pattern and emits the first laser light and the second laser light, a focusing unit configured to form a first focal point by focusing the first laser light and configured to form a second focal point by focusing the second laser light, and a control unit configured to control the spatial light modulator. The control unit causes the spatial light modulator to display the modulation pattern generated based on a focal length of the focusing unit, such that, by causing the focusing unit to focus the first laser light and the second laser light emitted from the spatial light modulator, the first focal point is located at a first position on the sample side with respect to the transmissive member, the second focal point is located at a second position on the transmissive member side with respect to the first focal point, and a distance between the first focal point and the second focal point in an optical axis direction of the first laser light and the second laser light is set to a set distance. The laser irradiation unit simultaneously performs ablation processing of the sample using the first laser light and ablation processing of particles, which are generated by the ablation processing of the sample, using the second laser light”.

A laser processing method according to the present disclosure is [13] “a laser processing method using a laser processing device including a disposition unit on which a sample is disposed, a laser output unit for outputting laser light, a laser irradiation unit for irradiating the sample, which is disposed on the disposition unit, with the laser light output from the laser output unit, and a transmissive member that is disposed on an optical axis of the laser light between the sample disposed on the disposition unit and the laser irradiation unit, and that transmits the laser light, the laser processing method including: a processing step of performing ablation processing using a first laser light and a second laser light generated from the laser light. The laser irradiation unit includes a spatial light modulator that displays a modulation pattern, and that generates the first laser light and the second laser light from the laser light by modulating the laser light in accordance with the modulation pattern and emits the first laser light and the second laser light, a focusing unit for forming a first focal point by focusing the first laser light and forming a second focal point by focusing the second laser light, and a control unit for controlling the spatial light modulator. The processing step includes a first step of causing the spatial light modulator to display the modulation pattern generated based on a focal length of the focusing unit, such that, by causing the focusing unit to focus the first laser light and the second laser light emitted from the spatial light modulator, the first focal point is located at a first position on the sample side with respect to the transmissive member, the second focal point is located at a second position on the transmissive member side with respect to the first focal point, and a distance between the first focal point and the second focal point in an optical axis direction of the first laser light and the second laser light is set to a set distance, and a second step of simultaneously performing ablation processing of the sample using the first laser light and ablation processing of particles, which are generated by the ablation processing of the sample, using the second laser light, after the first step”.

In the laser processing device and the laser processing method, the spatial light modulator generates the first laser light and the second laser light by modulating the laser light output from the laser output unit in accordance with the modulation pattern, and the focusing unit forms the first focal point of the first laser light and the second focal point of the second laser light by focusing the first laser light and the second laser light generated by the spatial light modulator. At this time, the modulation pattern generated such that the first focal point is located at the first position on the sample side with respect to the transmissive member and the second focal point is located at the second position on the transmissive member side with respect to the first focal point is displayed on the spatial light modulator. Accordingly, ablation processing of the sample using the first laser light and ablation processing of the particles, which are generated by the ablation processing of the sample, using the second laser light are performed simultaneously. Therefore, it is possible to suppress a decrease in the transmittance of the transmissive member due to adhesion of the particles generated by the ablation processing of the sample while shortening the processing time.

Here, the distance between the sample and the transmissive member may change depending on the size of the sample, the shape and size of the transmissive member, or the like. Therefore, in order to effectively and simultaneously perform ablation processing of the sample using the first laser light and ablation processing of the particles using the second laser light, it is desirable that the distance between the first focal point of the first laser light and the second focal point of the second laser light is set to an appropriate distance. In contrast, in the laser processing device and the laser processing method, the modulation pattern generated based on the focal length of the focusing unit, such that the distance between the first focal point and the second focal point in the optical axis direction of the first laser light and the second laser light becomes a desired set distance, is displayed on the spatial light modulator. Therefore, the distance between the first focal point of the first laser light and the second focal point of the second laser light can be set to an appropriate distance, and ablation processing of the sample using the first laser light and ablation processing of the particles using the second laser light can be performed effectively and simultaneously. As described above, according to the laser processing device and the laser processing method, it is possible to effectively suppress a decrease in the transmittance of the transmissive member while shortening the processing time.

Incidentally, in [1] and [13] above, it is specified that the transmissive member is disposed on the optical axis of the laser light between the sample disposed on the disposition unit and the laser irradiation unit. Meanwhile, the spatial light modulator of the laser irradiation unit generates the first laser light and the second laser light from the laser light. Therefore, specifically, the transmissive member is disposed on the optical axis of the first laser light and the second laser light as the laser light between the sample disposed on the disposition unit and the laser irradiation unit.

A laser processing device according to the present disclosure may be [2] “the laser processing device according to [1], in which the spatial light modulator displays the modulation pattern including a lens pattern that focuses only a portion of the laser light, and generates the second laser light including the portion of the laser light and the first laser light including a remainder of the laser light by modulating the laser light in accordance with the modulation pattern. The control unit causes the spatial light modulator to display the modulation pattern, which includes the lens pattern having a focal length calculated based on the focal length of the focusing unit and the set distance, such that the distance between the first focal point and the second focal point becomes the set distance”. In this case, by using the modulation pattern including the lens pattern that focuses only a portion of the laser light, it is possible to suitably set the distance between first focal point and the second focal point to a desired set distance while generating the first laser light and the second laser light.

A laser processing device according to the present disclosure may be [3] “the laser processing device according to [1] or [2] above, in which the control unit causes the spatial light modulator to display the modulation pattern generated such that a ratio between an intensity of the first laser light at the first focal point and an intensity of the second laser light at the second focal point becomes a set ratio”. In this case, the ratio between the intensity of the first laser light at the first focal point and the intensity of the second laser light at the second focal point can be set to a desired set ratio suitable for each processing.

A laser processing device according to the present disclosure may be [4] “the laser processing device according to any one of [1] to above, in which the control unit causes the spatial light modulator to display the modulation pattern generated based on irradiation conditions of the first laser light and irradiation conditions of the second laser light”. In this case, the irradiation conditions of the first laser light and the irradiation conditions of the second laser light can be set to desired conditions.

A laser processing device according to the present disclosure may be [5] “the laser processing device according to [4] above, in which the irradiation conditions of the second laser light includes a condition under which a beam pattern of the second laser light at the second focal point becomes a top hat shape”. In this case, ablation processing of the particles, which are generated by the ablation processing of the sample, using the second laser light can be efficiently performed.

A laser processing device according to the present disclosure may be [6] “the laser processing device according to [4], in which the irradiation conditions of the second laser light include a condition under which a plurality of the second focal points are formed along the optical axis direction of the second laser light”. In this case, ablation processing of the particles, which are generated by the ablation processing of the sample, using the second laser light can be performed over a wider range in the optical axis direction of the second laser light. Therefore, for example, even when the second focal point is shifted in the optical axis direction or even when the processing position (for example, a position on the surface of the transmissive member) is shifted in the optical axis direction, due to environmental changes, changes over time, or the like, stable ablation processing can be performed.

A laser processing device according to the present disclosure may be [7] “the laser processing device according to any one of [4] to above, in which the irradiation conditions of the first laser light include a condition under which a plurality of the first focal points are formed along a direction intersecting the optical axis direction of the first laser light”. In this case, ablation processing of the sample can be efficiently performed. In addition, in this case, for example, by adjusting the polarization direction of the first laser light at the plurality of first focal points arranged along the direction intersecting the optical axis direction of the first laser light (for example, setting the polarization directions to be orthogonal to each other between adjacent first focal points), the formation of a fine periodic structure on the processed cross section of the sample can be suppressed.

A laser processing device according to the present disclosure may be [8] “the laser processing device according to any one of [1] to above, in which the laser irradiation unit includes a variable attenuator configured to adjust an output of the laser light”. In this case, the output (processing point output) of the first laser light at the first focal point P1 can be set to a desired value.

A laser processing device according to the present disclosure may be [9] “the laser processing device according to any one of [1] to above, in which the laser irradiation unit includes a half-wave plate that is disposed in front of the spatial light modulator, and that controls a polarization direction of the laser light incident on the spatial light modulator”. In this case, the ratio between modulated light that is a portion of the laser light modulated by the spatial light modulator and unmodulated light that is a portion of the laser light not modulated by the spatial light modulator can be adjusted.

A laser processing device according to the present disclosure may be [10] “the laser processing device according to any one of [1] to above, in which a pulse width of the laser light is 1 ps or less”. In this case, ablation processing can be effectively performed. In addition, in this case, changes in the properties of the processed cross section due to heat can be suppressed by using an ultrashort-pulse laser having a pulse width of 1 ps or less.

A laser processing device according to the present disclosure may be [11] “the laser processing device according to any one of [1] to above further includes a distance measurement unit configured to measure a distance between the sample and the transmissive member by detecting light reflected by a laser light incident surface of the sample and light reflected by a surface on the sample side of the transmissive member. The control unit acquires the set distance based on the distance measured by the distance measurement unit”. In this case, even when the distance between the sample and the transmissive member is unknown, the distance between the first focal point and the second focal point can be set to a desired set distance, based on the measurement result from the distance measurement unit.

A microscope device according to the present disclosure may be “a microscope device including: the laser processing device according to any one of [1] to [11] above; and a microscope unit configured to observe the sample disposed on the disposition unit”. In this case, it is possible to provide the microscope device capable of suppressing a decrease in the transmittance of the transmissive member.

### Advantageous Effects of Invention

According to the present disclosure, it is possible to provide the laser processing device, the microscope device, and the laser processing method capable of suppressing a decrease in the transmittance of the transmissive member.

### BRIEF DESCRIPTION OF DRAWINGS

FIG. 1 is a schematic view showing a part of a microscope device according to the present embodiment.

FIG. 2 is a schematic view showing the remaining portion of the microscope device shown in FIG. 1.

FIG. 3 is a schematic view showing a part of a laser irradiation unit shown in FIG. 2.

FIG. 4 is a schematic view showing the relationship between a first focal point and a second focal point.

FIG. 5 is a flowchart showing one example of a laser processing method according to the present embodiment.

FIG. 6 is a flowchart showing specific steps of step S102 shown in FIG. 5.

FIG. 7 is a graph showing the relationship between the gradation value of a Fresnel lens pattern and the intensity of second laser light at the second focal point.

FIG. 8 is a schematic view showing a distance measurement unit according to a modification example.

### DESCRIPTION OF EMBODIMENTS

Hereinafter, one embodiment of a laser processing device, a microscope device including the laser processing device, and a laser processing method according to the present disclosure will be described with reference to the drawings. Incidentally, in the description of each drawing, the same or corresponding elements are denoted by the same reference signs, and duplicate descriptions may be omitted.

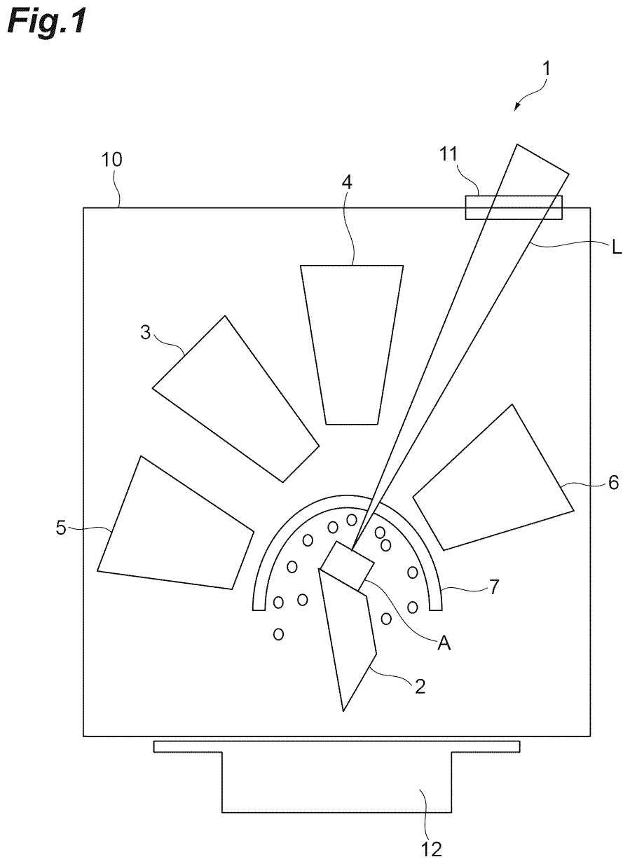

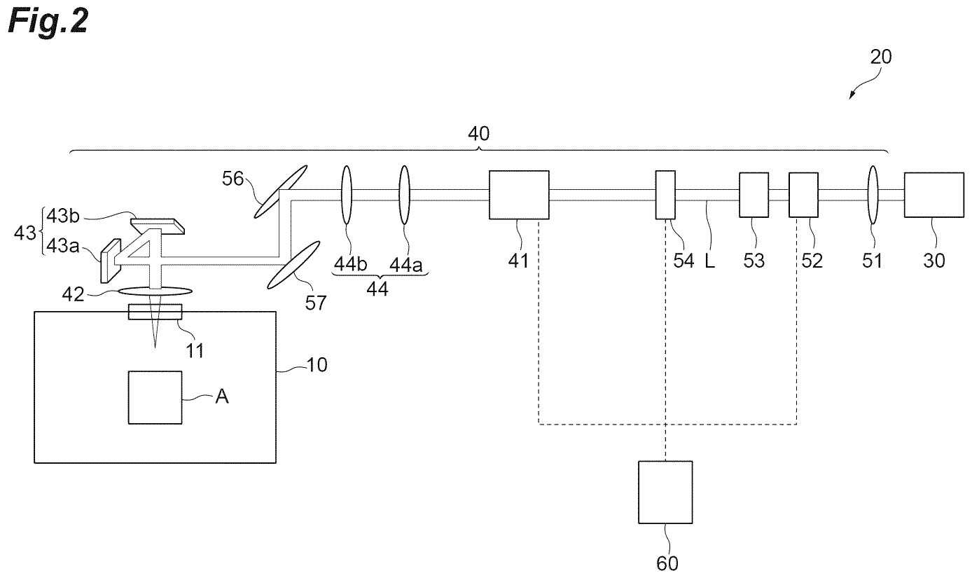

FIG. 1 is a schematic view showing a part of a microscope device according to the present embodiment. FIG. 2 is a schematic view showing the remaining portion of the microscope device shown in FIG. 1. A microscope device 1 shown in FIGS. 1 and 2 is, as will be described later, a device that includes a focused ion beam (FIB) device that performs etching on a sample by irradiating the sample with focused ions (for example, Ga ions); a scanning electron microscope (SEM) device that observes the sample by irradiating the sample with an electron beam; and a laser processing device that performs laser processing (here, ablation processing) on the sample by irradiating the sample with laser light, and that enables, by means of the SEM device, observation of a processed cross section of the sample formed by processing performed by the FIB device and/or the laser processing device.

The microscope device 1 includes a sample holder (disposition unit) 2, a beam irradiation unit 3, a first microscope unit (microscope unit) 4, a second microscope unit (microscope unit) 5, a cover 7 (transmissive member), a chamber 10, and a laser processing device 20. A sample A is disposed on the sample holder 2. The sample holder 2 may support the sample A without fixing the sample A as in a case in which the sample A is simply placed, or may fix and hold the sample A, for example, through affixing or the like. Here, the sample holder 2 holds the sample A. The beam irradiation unit 3 serves to irradiate the sample A held (disposed) (hereinafter, the same) by the sample holder 2 with a focused ion beam. Therefore, the beam irradiation unit 3 may include at least a focused ion beam emission unit of the FIB device.

The first microscope unit 4 serves to observe the sample A held by the sample holder 2. More specifically, the first microscope unit 4 is configured to be able to acquire an image of the sample A (observe the sample A) by irradiating the sample A held by the sample holder 2 with an electron beam, and detecting secondary electrons or the like generated in the sample A. Therefore, the first microscope unit 4 may be at least a part of the SEM device that includes an electron beam emission unit and a detection unit.

Similarly to the first microscope unit 4, the second microscope unit 5 serves to observe the sample A held by the sample holder 2. More specifically, the second microscope unit 5 can acquire information on the crystal structure or the like of the sample A (observe the sample A) by irradiating the sample A held by the sample holder 2 with an electron beam, and detecting the electron beam scattered by the sample A. That is, as one example, the second microscope unit 5 is a part of the SEM device using an electron backscatter diffraction (EBSD) method, and may be a part of the SEM device including at least an electron beam emission unit and a detection unit. Incidentally, the microscope device 1 may include a transmission electron microscope (TEM) device instead of (or in addition to) the SEM device. In this case, the first microscope unit 4 and the second microscope unit 5 may be at least a part of the TEM device.

The cover 7 is made of a material that transmits laser light L to be described later, and is provided to cover the sample A held by the sample holder 2. Accordingly, the cover 7 may be disposed at a reference position interposed between the sample holder 2 and the beam irradiation unit 3, the first microscope unit 4, and the second microscope unit 5 in the optical path of the laser light L. Incidentally, the cover 7 is configured to be movable from the reference position such that the cover 7 is not interposed between the sample holder 2 and the beam irradiation unit 3, the first microscope unit 4, and the second microscope unit 5.

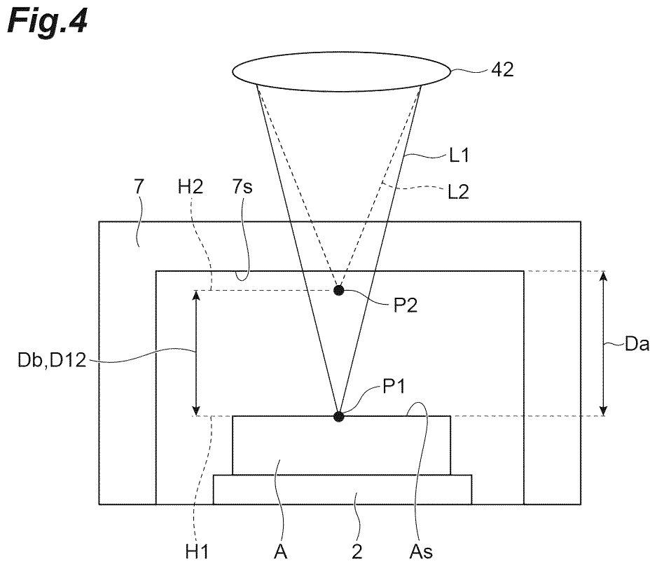

Incidentally, the cover 7 may be formed in a box shape, or may be formed in a plate shape. When the cover 7 has a box shape, the cover 7 may be formed, for example, in a rectangular box shape with one side open (the example of FIG. 4) or in a box shape with one side open and a semicircular cross section (the example of FIG. 1). In this case, in a state where the sample A is disposed inside the box, the cover 7 may be disposed such that an open portion of the box faces the bottom portion side of the chamber 10 and a bottom portion of the box faces the side on which the beam irradiation unit 3, the first microscope unit 4, and the second microscope unit 5 are located. At this time, an edge portion of the box forming the open portion may be in contact with a bottom portion of the chamber 10, or may be spaced apart from the bottom portion of the chamber 10.

The chamber 10 accommodates the sample holder 2, the beam irradiation unit 3, the first microscope unit 4, the second microscope unit 5, and the cover 7. An incident portion 11 for the laser light L that is formed in a window shape from a material that transmits the laser light L is formed in the chamber 10. In addition, an evacuation portion 12 for depressurization (creating a vacuum) by evacuation of the inside of the chamber 10 is formed in the chamber 10. Furthermore, another unit 6 for processing or observing the sample A held by the sample holder 2 may be provided inside the chamber 10.

The laser processing device 20 includes a laser output unit 30 and a laser irradiation unit 40. The laser output unit 30 serves to output the laser light L having ultrashort pulses at low fluence. The pulse width of the laser light L output from the laser output unit 30 is, for example, 1 ps or less. In addition, as one example, the fact that the laser light L has low fluence may indicate that the energy density of the laser light L is an energy density in the vicinity of a processing threshold value of the sample A, which is determined such that ablation processing is induced during laser processing of the sample A. The laser irradiation unit 40 serves to irradiate the sample A held by the sample holder 2 with the laser light L output from the laser output unit 30. The laser light L output from the laser output unit 30 is guided by the laser irradiation unit 40, and is incident into the chamber 10 through the incident portion 11.

The laser irradiation unit 40 includes a spatial light modulator 41 and a galvanometer scanner 43. The spatial light modulator 41 modulates the laser light output from the laser output unit 30 in accordance with a modulation pattern, and emits the modulated laser light. More specifically, the spatial light modulator 41 is, for example, a liquid crystal on silicon-spatial light modulator (LCOS-SLM), and displays a modulation pattern on a liquid crystal layer, thereby modulating the laser light L, which is incident on and emitted from the liquid crystal layer, in accordance with the modulation pattern.

The spatial light modulator 41 can suppress the expansion of a spot system at the focal position of the laser light L, for example, as will be described later, by modulating the laser light L such that the laser light L has a plurality of focal points in an optical axis direction, or modulating the laser light L to correct aberrations occurring when the laser light passes through the transmissive member such as the cover 7 or the incident portion 11.

The galvanometer scanner 43 includes mirrors 43a and 43b, and irradiates the sample A held by the sample holder 2 with the laser light L emitted from the spatial light modulator 41, while scanning the sample A by driving the mirrors 43a and 43b. The laser light L emitted from the galvanometer scanner 43 is focused toward the sample A by a lens (focusing unit) 42. The lens 42 is, for example, an fθ lens.

The laser irradiation unit 40 includes a relay optical system 44. The relay optical system 44 is disposed between the spatial light modulator 41 and the galvanometer scanner 43. The relay optical system 44 includes a pair of lenses 44a and 44b, and serves to transfer an image of the laser light L modulated by the spatial light modulator 41 onto the lens 42. The optical path of the laser light L emitted from the spatial light modulator 41 and passing through the relay optical system 44 is adjusted by predetermined mirrors 56 and 57, and the laser light L is then provided to the galvanometer scanner 43.

The laser irradiation unit 40 further includes a collimating lens 51, an output control unit 52, a beam diameter control unit 53, and a half-wave plate 54 that are disposed in order on the optical path of the laser light L from the laser output unit 30 toward the spatial light modulator 41. The collimating lens 51 collimates the laser light L output from the laser output unit 30, and emits the collimated laser light L. Therefore, the collimated laser light L is incident on the spatial light modulator 41. The collimating lens 51 may be omitted.

The output control unit 52 is, for example, a variable attenuator, and adjusts the output of the laser light L output from the laser output unit 30. The beam diameter control unit 53 is, for example, a beam expander, and adjusts the beam diameter of the laser light L output from the laser output unit 30. In such a manner, the output control unit 52 and the beam diameter control unit 53 are disposed between the spatial light modulator 41 and the laser output unit 30, and function as the adjustment units that adjust the output and beam diameter of the laser light L.

The half-wave plate 54 is disposed in front of the spatial light modulator 41. The half-wave plate 54 changes the polarization direction of the laser light L output from the laser output unit 30. As described above, the laser light L incident on the spatial light modulator 41 is modulated and then incident into the chamber 10 through the galvanometer scanner 43, and is provided for scanning of the sample A.

In the microscope device 1 described above, the processing of the sample A using a focused ion beam from the beam irradiation unit 3 and the processing of the sample A using the laser light L from the laser processing device 20 can be performed. When a focused ion beam is used, the sample A can be processed and observed with high accuracy. On the other hand, when the laser light L is used, a large area of the sample A can be processed and observed with high throughput.

The laser processing device 20 further includes a control unit 60. The control unit 60 can control at least the spatial light modulator 41, the output control unit 52, and the half-wave plate 54. The control unit 60 is configured as a computer device including a processor, a memory, a storage, a communication device, and the like. In the control unit 60, the processor executes various processes for controlling each part such as the spatial light modulator 41 by executing software (program) loaded into the memory or the like, and controlling reading and writing of data in the memory and the storage and communication via the communication device.

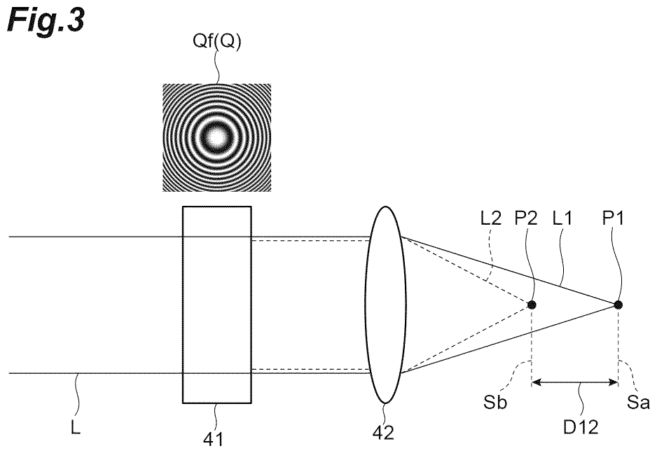

Subsequently, the operation of each part of the laser irradiation unit 40 will be described in more detail. FIG. 3 is a schematic view showing a part of the laser irradiation unit shown in FIG. 2. As shown in FIG. 3, under the control of the control unit 60, the spatial light modulator 41 displays a modulation pattern Q, generates a first laser light L1 and a second laser light L2 from the laser light L by modulating the laser light L in accordance with the modulation pattern Q, and emits the first laser light L1 and the second laser light L2.

Therefore, the control unit 60 controls the half-wave plate 54 (for example, adjusting the angle around the optical axis of the laser light L), which is disposed in front of the spatial light modulator 41, to convert a polarization direction of the laser light L, which is emitted from the half-wave plate 54, into a polarization direction including a first polarization direction that is the direction of first linearly polarized light (for example, p-polarized light) and second linearly polarized light (for example, s-polarized light) orthogonal to the first polarization direction.

In addition, the control unit 60 controls the spatial light modulator 41 to display the modulation pattern Q, which includes a Fresnel lens pattern (lens pattern) Qf that focuses only a portion of the laser light L, on the spatial light modulator 41, and generates the second laser light L2 including the portion of the laser light L and the first laser light L1 including the remainder of the laser light L by modulating the laser light L in accordance with the modulation pattern Q. The Fresnel lens pattern Qf has a focal length fo.

Accordingly, for example, a portion of the component of the laser light L in the first polarization direction is modulated by the Fresnel lens pattern Qf and is emitted from the spatial light modulator 41 as the second laser light L2 while being focused, and the remainder of the component in the first polarization direction and the component of the laser light L in a second polarization direction are not modulated by the Fresnel lens pattern Qf and are emitted from the spatial light modulator 41 as the first laser light L1 without being focused. In other words, the second laser light L2 includes a portion (modulated light) of the laser light L modulated by the Fresnel lens pattern Qf in the spatial light modulator 41. In addition, the first laser light L1 includes the remainder (unmodulated light) of the laser light L.

The lens 42 forms a first focal point P1 by focusing the first laser light L1 emitted from the spatial light modulator 41, and forms a second focal point P2 by focusing the second laser light L2 emitted from the spatial light modulator 41. The first focal point P1 is formed on an (original) focal plane Sa spaced apart from the lens 42 by a focal length f of the lens 42. The second focal point P2 is a position on the spatial light modulator 41 side with respect to the first focal point P1, and is formed on a combined focal plane Sb of the Fresnel lens pattern Qf and the lens 42.

A distance D12 between the first focal point Pl and the second focal point P2 in an optical axis direction of the first laser light L1 and the second laser light L2 (an offset between the first focal point Pl and the second focal point P2), that is, the spacing between the focal plane Sa and the combined focal plane Sb, is expressed by the following equation (1) using the focal length f of the lens 42 and a combined focal length fo of the Fresnel lens pattern Of and the lens 42.

Distance D12=f−f_{G} (1)

In addition, the combined focal length f_{G} is expressed by the following equation (2) using the focal length f of the lens 42 and the focal length f_{Q} of the Fresnel lens pattern Qf.

Combined focal length f_{G}=(f·f_{Q})/(f_{Q}+f) (2)

Therefore, the distance D12 between the first focal point P1 and the second focal point P2 may be variable by adjusting the focal length fo of the Fresnel lens pattern Qf. The control unit 60 sets the distance D12 between the first focal point P1 and the second focal point P2 to a desired set distance by appropriately adjusting the Fresnel lens pattern Of included in the modulation pattern Q displayed on the spatial light modulator 41. Subsequently, this point will be described.

FIG. 4 is a schematic view showing the relationship between the first focal point and the second focal point. As shown in FIGS. 3 and 4, the first focal point P1 is located at a first position H1 on the sample A side with respect to the cover 7, and the second focal point P2 is located at a second position H2 on the cover 7 side with respect to the first focal point P1. Accordingly, the first laser light L1 having the first focal point Pl is provided for ablation processing of the sample A, and the second laser light L2 having the second focal point P2 is provided for ablation processing of particles generated from the sample A by the ablation processing of the sample A (hereinafter, simply may be referred to as “particles”). The particles generated in the sample A include particles floating between the sample A and the cover 7 or particles adhered to a surface 7s on the sample A side of the cover 7.

In the illustrated example, the first position H1 is a position on a surface As on the cover 7 side of the sample A, and the second position H2 is a position on the sample A side with respect to the surface 7s on the sample A side of the cover 7. However, the first position H1 may be any position where ablation processing can be performed on the sample A using the first laser light L1 having the first focal point P1 located at the first position H1, and may be any position that is at least closer to the sample A side than to the cover 7 (that is, any position closer to the sample A than to the cover 7).

In addition, the second position H2 may be any position where ablation processing can be performed on the particles using the second laser light L2 having the second focal point P2 located at the second position H2, and may be any position that is at least closer to the cover 7 side than the first position H1. For example, the second position H2 may be any of a position outside the cover 7 that is closer to the sample A side than the surface 7s of the cover 7 as illustrated, a position on the surface 7s of the cover 7, a position inside the cover 7, and a position outside the cover 7 on the side opposite the surface 7s of the cover 7.

A desired set distance Db between the first focal point P1 and the second focal point P2 is set to the distance at which ablation processing of the sample A using the first laser light L1 and ablation processing of the particles using the second laser light L2 can be executed simultaneously. The set distance Db may be set based on a distance Da between the surface As of the sample A and the surface 7s of the cover 7. The set distance Db may coincide with the distance Da, or may not coincide with the distance Da (in the illustrated example, shorter than the distance Da). The distance D12 between the first focal point P1 and the second focal point P2 is set to the set distance Db.

In order to set the distance D12 to the set distance Db, since the set distance Db and the focal length f of the lens 42 are known values, as one example, the Fresnel lens pattern Of having a specific value, which is obtained by substituting the above equation (2) into the combined focal length fo in the equation in which the distance D12 in the above equation (1) is set to the set distance Db and solving the resulting equation for the focal length fo of the Fresnel lens pattern Qf, as the focal length may be generated.

As described above, the control unit 60 causes the spatial light modulator 41 to display the modulation pattern Q (including the Fresnel lens pattern Qf) generated based on the focal length f of the lens 42, such that, by causing the lens 42 to focus the first laser light L1 and the second laser light L2 emitted from the spatial light modulator 41, the first focal point P1 is located at the first position H1 on the sample A side with respect to the cover 7, the second focal point P2 is located at the second position H2 on the cover 7 side with respect to the first focal point P1, and the distance D12 between the first focal point Pl and the second focal point P2 in the optical axis direction of the first laser light L1 and the second laser light L2 is set to the set distance Db.

Accordingly, the laser irradiation unit 40 can simultaneously perform ablation processing of the sample A using the first laser light L1 and ablation processing of particles, which are generated by the ablation processing of the sample A, using the second laser light L2.

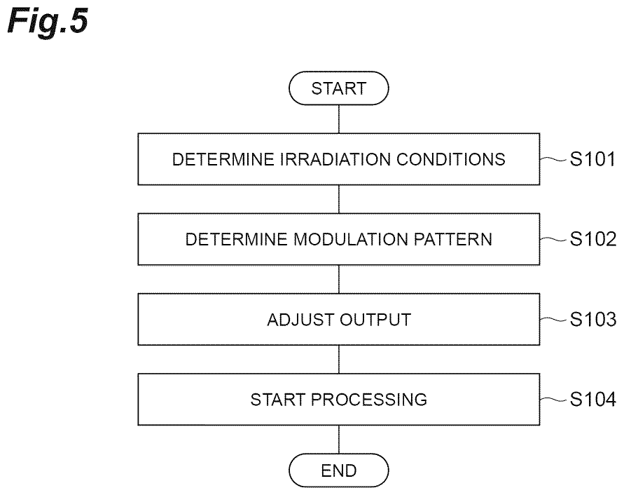

Subsequently, the operation of the laser irradiation unit 40 will be described in further detail using the laser processing method according to the present embodiment. FIG. 5 is a flowchart showing one example of the laser processing method according to the present embodiment. As shown in FIG. 5, in the laser processing method according to the present embodiment, first, the irradiation conditions of the laser light L are determined (step S101).

Specifically, in step S101, the patterns (irradiation conditions) at the processing points of the first laser light L1 and the second laser light L2 are determined. Here, as one example, regarding the second laser light L2, a condition under which the beam pattern of the second laser light L2 at the second focal point P2 has a top hat shape, or a condition under which a plurality of the second focal points P2 are formed along the optical axis direction of the second laser light L2 is determined as the irradiation condition. In addition, as one example, regarding the first laser light L1, a condition under which a plurality of the first focal points Pl are formed along a direction intersecting the optical axis direction of the first laser light LI is determined as the irradiation condition.

These irradiation conditions are related to the generation of the modulation pattern Q to be displayed on the spatial light modulator 41 in a later step. For example, in order to realize the irradiation condition under which the plurality of second focal points P2 are formed along the optical axis direction of the second laser light L2, the modulation pattern Q may be generated to include an axicon lens pattern. In addition, for example, in order to realize the irradiation condition under which the plurality of first focal points P1 are formed along the direction intersecting the optical axis direction of the first laser light L1, the modulation pattern Q may be generated to include a diffraction grating pattern that diffracts and branches the first laser light L1. Therefore, in the next step, the modulation pattern Q to be displayed on the spatial light modulator 41 is determined (step S102: processing step). Step S102 will be described more specifically.

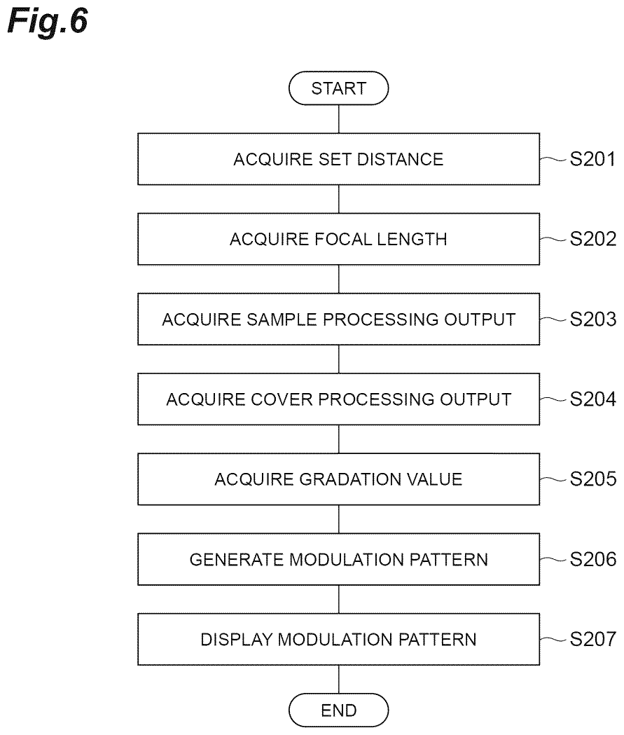

FIG. 6 is a flowchart showing specific steps of step S102 shown in FIG. 5. As shown in FIG. 6, in step S102, the control unit 60 acquires various conditions for generating the modulation pattern Q to be displayed on the spatial light modulator 41. That is, here, first, the control unit 60 acquires the set distance Db (step S201). The set distance Db is determined based on the distance Da between the sample A and the cover 7. When the design value of the distance Da between the sample A and the cover 7 is known, the design value may be used, and when the design value is unknown, the distance Da may be acquired through measurement using an optical method (distance measurement unit 70) as will be described later. The control unit 60 can acquire the set distance Db, for example, by accepting an input of the set distance Db determined based on the distance Da.

Next, the control unit 60 acquires the focal length fo of the Fresnel lens pattern Qf (step S202). As described above, the focal length fo may be calculated using the above equation (1) and the above equation (2) based on the set distance Db and the focal length f of the lens 42 that are known. The control unit 60 can acquire the focal length f_{Q}, for example, by accepting an input of the calculated focal length fo of the Fresnel lens pattern Qf.

Next, the control unit 60 acquires the output value (processing point output) of the first laser light L1 at the first focal point P1 for ablation processing of the sample A (step S203). In addition, the control unit 60 acquires the output value (processing point output) of the second laser light L2 at the second focal point P2 for ablation processing of the particles on the cover 7 side (step S204). The control unit 60 can acquire the output value, for example, by accepting an input of the output value. Incidentally, the processing point output of the second laser light L2 may be a fixed value when the material of the cover 7 is not changed.

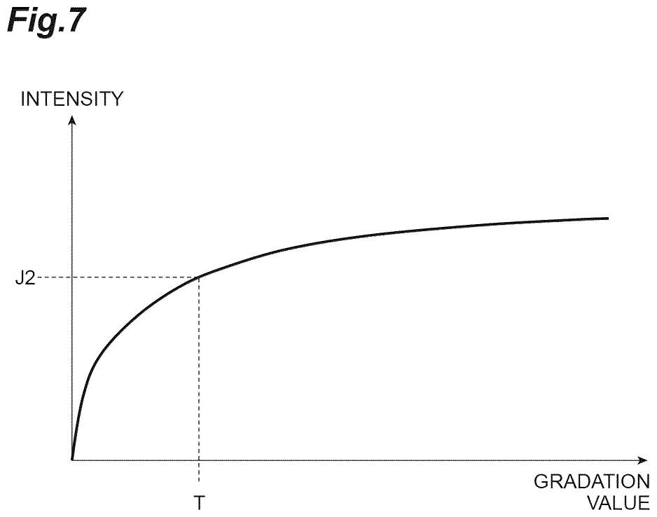

Next, the control unit 60 acquires the gradation value of the Fresnel lens pattern Qf (phase image) (step S205). The gradation value of the Fresnel lens pattern Of is determined such that the ratio between the intensity of the first laser light L1 at the first focal point P1 and the intensity of the second laser light L2 at the second focal point P2 becomes a desired set ratio. FIG. 7 is a graph showing the relationship between the gradation value of the Fresnel lens pattern Qf and an intensity J2 of the second laser light L2 at the second focal point P2. Here, a gradation value T that realizes the intensity J2 of the second laser light L2 at which the ratio between the intensity of the first laser light L1 at the first focal point P1 and the intensity of the second laser light L2 at the second focal point P2 becomes a desired set ratio is determined based on the graph (table) shown in FIG. 7. The control unit 60 can acquire the gradation value T, for example, by accepting an input of the selected gradation value T.

Next, the control unit 60 generates the modulation pattern Q based on the various conditions acquired above (step S206: first step). Specifically, the control unit 60 determines the Fresnel lens pattern Qf based on the focal length fo of the Fresnel lens pattern Qf acquired in step S202 and the gradation value of the Fresnel lens pattern Qf acquired in step S205. In addition, the control unit 60 determines, for example, an axicon lens pattern or a diffraction grating pattern based on the irradiation conditions determined in step S101. Then, the control unit 60 generates the modulation pattern Q in which the Fresnel lens pattern Qf, the axicon lens pattern, the diffraction grating pattern, and other patterns (for example, an aberration correction pattern and the like) are superimposed.

That is, the control unit 60 generates the modulation pattern Q based on (in consideration of) the set distance Db between the first focal point P1 and the second focal point P2 in the optical axis direction of the first laser light L1 and the second laser light L2, the focal length f of the lens 42, the gradation value T of the Fresnel lens pattern Of which is set such that the ratio between the intensity of the first laser light L1 at the first focal point P1 and the intensity of the second laser light L2 at the second focal point P2 becomes the set ratio, and the irradiation conditions of the first laser light L1 and the second laser light L2.

Thereafter, the control unit 60 causes the spatial light modulator 41 to display the modulation pattern Q generated in step S206 (step S207: first step). Accordingly, in the laser irradiation unit 40, the laser light L is modulated by the modulation pattern Q in the spatial light modulator 41, and the first laser light L1 and the second laser light L2 are generated from the laser light L. In addition, the first laser light L1 and the second laser light L2 are focused by the lens 42, and the first focal point Pl and the second focal point P2 are formed simultaneously. At this time, the relationship between the first focal point Pl and the second focal point P2 is established such that, in accordance with the modulation pattern Q (Fresnel lens pattern Qf) and the lens 42, the first focal point P1 is located at the first position H1 on the sample A side with respect to the cover 7, the second focal point P2 is located at the second position H2 on the cover 7 side with respect to the first focal point P1, and the distance between the first focal point P1 and the second focal point P2 in the optical axis direction of the first laser light L1 and the second laser light L2 becomes the set distance Db.

As shown in FIG. 5, in the next step, the control unit 60 controls, for example, the output control unit 52, which is a variable attenuator, to adjust the output of the laser light L (step S103). In step S103, the control unit 60 controls the output control unit 52 such that the output of the first laser light L1 at the first focal point P1 becomes the processing point output acquired in step S203, and the output of the second laser light L2 at the second focal point P2 becomes the processing point output acquired in step S204.

Then, for example, in a state where the control unit 60 causes the spatial light modulator 41 to display the modulation pattern Q, the control unit 60 controls the laser output unit 30 to output the laser light L, and controls the galvanometer scanner 43 to scan the sample A with the first laser light L1 and the second laser light L2, thereby executing ablation processing of the sample A and ablation processing of the particles (step S104: second step). In step S104, the laser irradiation unit 40 simultaneously performs ablation processing of the sample A using the first laser light L1 and ablation processing of the particles, which are generated by the ablation processing of the sample A, using the second laser light A2.

In such a manner, the laser processing method according to the present embodiment includes the processing step (step S102, steps S201 to S207, and step S104) of performing ablation processing using the first laser light L1 and the second laser light L2 generated from the laser light L. In addition, the processing step includes the first step (steps S201 to S207) of causing the spatial light modulator 41 to display the modulation pattern Q generated based on the focal length f of the lens 42, such that, by causing the lens 42 to focus the first laser light L1 and the second laser light L2 emitted from the spatial light modulator 41, the first focal point P1 is located at the first position H1 on the sample A side with respect to the cover 7, the second focal point P2 is located at the second position H2 on the cover 7 side with respect to the first focal point P1, and the distance between the first focal point Pl and the second focal point P2 in the optical axis direction of the first laser light L1 and the second laser light L2 is set to the set distance Db, and the second step (step S104) of simultaneously performing ablation processing of the sample A using the first laser light L1 and ablation processing of the particles, which are generated by the ablation processing of the sample A, using the second laser light L2, after the first step.

As described above, in the laser processing device 20 and the laser processing method according to the present embodiment, the spatial light modulator 41 generates the first laser light L1 and the second laser light L2 by modulating the laser light L output from the laser output unit 30 in accordance with the modulation pattern Q, and the lens 42 forms the first focal point P1 of the first laser light L1 and the second focal point P2 of the second laser light L2 by focusing the first laser light L1 and the second laser light L2 generated by the spatial light modulator 41.

At this time, the modulation pattern Q generated such that the first focal point P1 is located at the first position H1 on the sample A side with respect to the cover 7 and the second focal point P2 is located at the second position H2 on the cover 7 side with respect to the first focal point P1 is displayed on the spatial light modulator 41. Accordingly, ablation processing of the sample A using the first laser light L1 and ablation processing of the particles, which are generated by the ablation processing of the sample A, using the second laser light L2 are performed simultaneously. Therefore, it is possible to suppress a decrease in the transmittance of the cover 7 due to adhesion of the particles generated by the ablation processing of the sample A, while shortening the processing time.

Here, the distance between the sample A and the cover 7 may change depending on the size of the sample A, the shape and size of the cover 7, or the like. Therefore, in order to effectively and simultaneously perform ablation processing of the sample A using the first laser light L1 and ablation processing of the particles using the second laser light L2, it is desirable that the distance D12 between the first focal point Pl of the first laser light L1 and the second focal point P2 of the second laser light L2 is set to an appropriate distance.

In contrast, in the laser processing device 20 and the laser processing method according to the present embodiment, the modulation pattern Q (including the Fresnel lens pattern Qf) generated based on the focal length f of the lens 42, such that the distance D12 between the first focal point P1 and the second focal point P2 in the optical axis direction of the first laser light L1 and the second laser light L2 becomes the desired set distance Db, is displayed on the spatial light modulator 41. Therefore, the distance D12 between the first focal point P1 and the second focal point P2 can be set to the appropriate set distance Db, and ablation processing of the sample A using the first laser light L1 and ablation processing of the particles using the second laser light L2 can be performed effectively and simultaneously. As described above, in the laser processing device 20 and the laser processing method according to the present embodiment, it is possible to effectively suppress a decrease in the transmittance of the cover 7 while shortening the processing time.

In addition, in the laser processing device 20 according to the present embodiment, the spatial light modulator 41 displays the modulation pattern Q including the Fresnel lens pattern Qf that focuses only a portion of the laser light L, and generates the second laser light L2 including the portion (modulated light) of the laser light L and the first laser light L1 including the remainder (unmodulated light) of the laser light L by modulating the laser light L in accordance with the modulation pattern Q. Furthermore, the control unit 60 causes the spatial light modulator 41 to display the modulation pattern Q, which includes the Fresnel lens pattern Of having the focal length fo calculated based on the focal length f of the lens 42 and the set distance Db, such that the distance D12 between the first focal point Pl and the second focal point P2 becomes the set distance Db. Accordingly, by using the modulation pattern Q including the Fresnel lens pattern Of that focuses only a portion of the laser light L, it is possible to suitably set the distance D12 between first focal point Pl and the second focal point P2 to the desired set distance Db while generating the first laser light L1 and the second laser light L2.

In addition, in the laser processing device 20 according to the present embodiment, the control unit 60 causes the spatial light modulator 41 to display the modulation pattern Q generated such that the ratio between the intensity of the first laser light L1 at the first focal point Pl and the intensity (intensity J2) of the second laser light L2 at the second focal point P2 becomes the set ratio (that is, the modulation pattern Q including the Fresnel lens pattern Of having the gradation value T at which the ratio becomes the set ratio). Therefore, the ratio between the intensity of the first laser light L1 at the first focal point P1 and the intensity of the second laser light L2 at the second focal point P2 can be set to a desired set ratio suitable for each processing.

In addition, in the laser processing device 20 according to the present embodiment, the control unit 60 causes the spatial light modulator 41 to display the modulation pattern Q generated based on the irradiation conditions of the first laser light L1 and the irradiation conditions of the second laser light L2. Therefore, the irradiation conditions of the first laser light L1 and the irradiation conditions of the second laser light L2 can be set to desired conditions.

In addition, in the laser processing device 20 according to the present embodiment, the irradiation conditions of the second laser light L2 may include the condition under which the beam pattern of the second laser light L2 at the second focal point P2 has a top hat shape. In this case, ablation processing of the particles, which are generated by the ablation processing of the sample A, using the second laser light L2 can be efficiently performed.

In addition, in the laser processing device 20 according to the present embodiment, the irradiation conditions of the second laser light L2 may include the condition under which the plurality of the second focal points P2 are formed along the optical axis direction of the second laser light L2. In this case, ablation processing of the particles, which are generated by the ablation processing of the sample A, using the second laser light L2 can be performed over a wider range in the optical axis direction of the second laser light L2. Therefore, for example, even when the second focal point P2 is shifted in the optical axis direction or even when the processing position (for example, a position on the surface of the cover 7) is shifted in the optical axis direction, due to environmental changes, changes over time, or the like, stable ablation processing is can be performed.

In addition, in the laser processing device 20 according to the present embodiment, the irradiation conditions of the first laser light L1 may include the condition under which the plurality of the first focal points P1 are formed along the direction intersecting the optical axis direction of the first laser light L1. In this case, ablation processing of the sample A can be efficiently performed. In addition, in this case, for example, by adjusting the polarization direction of the first laser light L1 at the plurality of first focal points P1 arranged along the direction intersecting the optical axis direction of the first laser light LI (for example, setting the polarization directions to be orthogonal to each other between adjacent first focal points P1), the formation of a fine periodic structure on the processed cross section of the sample A can be suppressed.

In addition, in the laser processing device 20 according to the present embodiment, the laser irradiation unit 40 includes the output control unit 52 that is, for example, a variable attenuator for adjusting the output of the laser light L (that is, the first laser light LI and the second laser light L2). Therefore, the processing point outputs of the first laser light L1 and the second laser light L2 can be set to desired values.

In addition, in the laser processing device 20 according to the present embodiment, the laser irradiation unit 40 includes the half-wave plate 54 that is disposed in front of the spatial light modulator 41, and that controls the polarization direction of the laser light L incident on the spatial light modulator 41. Therefore, the ratio between modulated light that is a portion of the laser light L modulated by the spatial light modulator 41 and unmodulated light that is a portion of the laser light L not modulated by the spatial light modulator 41 can be adjusted.

In addition, in the laser processing device 20 according to the present embodiment, the pulse width of the laser light L is 1 ps or less. Therefore, ablation processing can be effectively performed. In addition, changes in the properties of the processed cross section of the sample A due to heat can be suppressed by using an ultrashort-pulse laser having a pulse width of 1 ps or less.

In addition, the microscope device 1 according to the present embodiment includes the laser processing device 20 according to the present embodiment and the first microscope unit 4 and the second microscope unit 5 for observing the sample A disposed on the sample holder 2. Therefore, the microscope device 1 capable of suppressing a decrease in the transmittance of the cover 7 is provided.

The above embodiment has described one aspect of the laser processing device, the microscope device, and the laser processing method according to the present invention. Therefore, the laser processing device, the microscope device, and the laser processing method according to the present invention are not limited to the above-described embodiment, and may be arbitrarily modified.

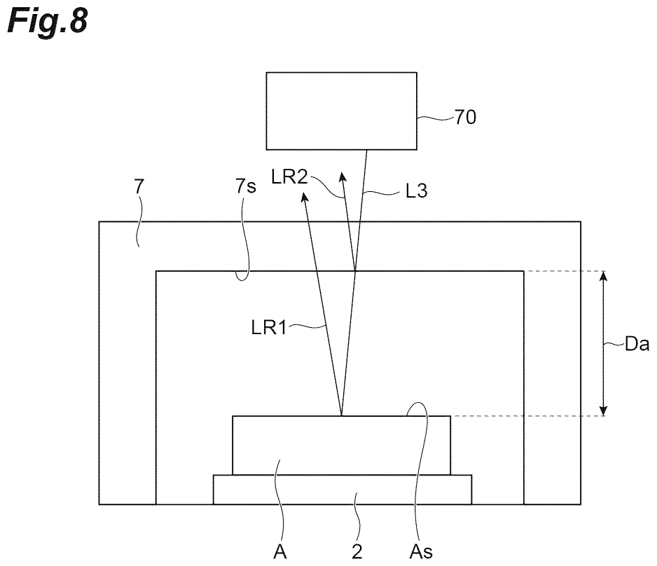

For example, as shown in FIG. 8, the laser processing device 20 can include the distance measurement unit 70. The distance measurement unit 70 emits laser beam L3 light source 10 emits laser light L3 for distance measurement toward the sample A and the cover 7. The laser light L3 for distance measurement has, for example, a wavelength different from the wavelength of the laser light L for processing. In addition, the distance measurement unit 70 measures the distance Da between the sample A and the cover 7 by detecting reflected light LR1 of the laser light L3 for distance measurement reflected by the surface As that is a laser light incident surface of the sample A, and reflected light LR2 of the laser light L3 for distance measurement reflected by the surface 7s on the sample A side of the cover 7. In this case, the control unit 60 can acquire the set distance Db based on the distance Da measured by the distance measurement unit 70.

In addition, in the above-described embodiment, an example in which the irradiation conditions of the first laser light L1 include the condition under which the plurality of the first focal points P1 are formed along the direction intersecting the optical axis direction of the first laser light L1 has been provided. In this example, the control unit 60 displays, on the spatial light modulator 41, the modulation pattern Q generated based on the irradiation condition so as to include a diffraction grating pattern for branching the first laser light L1. However, the irradiation conditions of the first laser light L1 is not limited thereto, and may include, for example, a condition under which a single first focal point P1 of the first laser light L1 is formed. In this case, the control unit 60 displays, on the spatial light modulator 41, the modulation pattern Q generated based on the irradiation condition so as not to include a diffraction grating pattern for branching the first laser light L1.

In addition, in the above-described embodiment, an example in which the irradiation conditions of the second laser light L2 include the condition under which the beam pattern of the second laser light L2 at the second focal point P2 has a top hat shape has been provided. However, the irradiation conditions of the second laser light L2 is not limited thereto, and may include, for example, a condition under which the beam pattern of the second laser light L2 at the second focal point P2 becomes a Gaussian beam. In this case, the control unit 60 can display, on the spatial light modulator 41, the modulation pattern Q generated based on the irradiation condition so as not to adjust the beam pattern of the second laser light L2 at the second focal point P2.

In addition, in the above-described embodiment, an example in which the irradiation conditions of the second laser light L2 include the condition under which the plurality of the second focal points P2 are formed along the optical axis direction of the second laser light L2 has been provided. In this example, the control unit 60 displays, on the spatial light modulator 41, the modulation pattern Q generated based on the irradiation condition so as to include an axicon lens pattern. However, the irradiation conditions of the second laser light L2 may include a condition under which a single second focal point P2 is formed along the optical axis direction of the second laser light L2. In this case, the control unit 60 displays, on the spatial light modulator 41, the modulation pattern Q generated based on the irradiation condition so as not to include an axicon lens pattern.

In such a manner, the control unit 60 can generate the modulation pattern Q based on (in consideration of) the irradiation conditions, regardless of whether any control is performed or not performed on the first laser light L1 and the second laser light L2.

Furthermore, in the above-described embodiment, the cover 7 has been provided as one example of a transmissive member disposed on the optical axis of the laser light L between the sample A disposed on the sample holder 2 and the laser irradiation unit 40. However, the transmissive member may be the incident portion 11 formed in the chamber 10.

Incidentally, in the above-described embodiment, it is stated that the optical axis of the first laser light L1 is assumed to be coincide with the optical axis of the second laser light L2, as in the expression “the distance D12 between the first focal point P1 and the second focal point P2 in the optical axis direction of the first laser light L1 and the second laser light L2”. On the other hand, when the modulation pattern Q displayed on the spatial light modulator 41 includes a diffraction grating pattern that diffracts and branches the first laser light L1, the optical axis of the modulated light of the first laser light L1 branched into a plurality of beams, that is modulated by the diffraction grating pattern may not coincide with the optical axis of the second laser light L2, and in this case, the optical axis of the unmodulated light (zeroth-order light) of the first laser light L1 branched into a plurality of beams, that is not modulated by the diffraction grating pattern coincides with the optical axis of the second laser light L2. Even in such a case, the optical axis of the first laser light L1 may be regarded as coinciding with the optical axis of the second laser light L2.

In addition, in the above-described embodiment, an example in which the second laser light L2 including modulated light modulated by the Fresnel lens pattern Of is focused closer to the cover 7 side and is provided for ablation processing of the particles, and the first laser light L1 including unmodulated light not modulated by the Fresnel lens pattern Qf is focused closer to the sample A side and is provided for ablation processing of the sample A has been described. However, by adjusting the Fresnel lens pattern Qf, the second focal point P2 of the second laser light L2 can also be formed on the sample side with respect to the first focal point P1 of the first laser light L1. That is, the second focal point P2 of the second laser light L2 can be formed at a position on the side opposite the spatial light modulator 41 with respect to the first focal point P1 of the first laser light L1. In this case, the second focal point P2 of the second laser light L2 substantially becomes the first focal point located at the first position on the sample A side with respect to the cover 7, and the first focal point P1 of the first laser light L1 substantially becomes the second focal point located at the second position on the cover 7 side with respect to the first focal point. In addition, in this case, ablation processing of the sample A can be performed using the second laser light L2, and ablation processing of the particles can be performed using the first laser light L1.

In addition, in the above-described embodiment, an example in which, after step S102 of determining the modulation pattern Q to be displayed on the spatial light modulator 41, step S103 of adjusting the output of the laser light L is executed has been described. However, step S103 may be executed before step S102.

### INDUSTRIAL APPLICABILITY

The laser processing device, the microscope device, and the laser processing method capable of suppressing a decrease in the transmittance of the transmissive member are provided.

### REFERENCE SIGNS LIST

1: microscope device, 2: sample holder (disposition unit), 4: first microscope unit (microscope unit), 5: second microscope unit (microscope unit), 7: cover (transmissive member), 20: laser processing device, 30: laser output unit, 40: laser irradiation unit, 41: spatial light modulator, 42: lens (focusing unit), 52: output control unit (variable attenuator), 54: half-wave plate, 60: control unit, A: sample, D12: distance, Db: set distance, f: focal length, L: laser light, L1: first laser light, L2: second laser light, P1: first focal point, P2: second focal point, Q: modulation pattern, Qf: Fresnel lens pattern.

1. A laser processing device, comprising:
a disposition unit on which a sample is disposed;
a laser output unit configured to output laser light;
a laser irradiation unit configured to irradiate the sample, which is disposed on the disposition unit, with the laser light output from the laser output unit; and
a transmissive member that is disposed on an optical axis of the laser light between the sample disposed on the disposition unit and the laser irradiation unit, and that transmits the laser light,
wherein the laser irradiation unit includes
a spatial light modulator configured to display a modulation pattern, and configured to generate a first laser light and a second laser light from the laser light by modulating the laser light in accordance with the modulation pattern and emits the first laser light and the second laser light,
a focusing unit configured to form a first focal point by focusing the first laser light and configured to form a second focal point by focusing the second laser light,
and a control unit configured to control the spatial light modulator,
the control unit causes the spatial light modulator to display the modulation pattern generated based on a focal length of the focusing unit, such that, by causing the focusing unit to focus the first laser light and the second laser light emitted from the spatial light modulator, the first focal point is located at a first position on the sample side with respect to the transmissive member, the second focal point is located at a second position on the transmissive member side with respect to the first focal point, and a distance between the first focal point and the second focal point in an optical axis direction of the first laser light and the second laser light is set to a set distance, and
the laser irradiation unit simultaneously performs ablation processing of the sample using the first laser light and ablation processing of particles, which are generated by the ablation processing of the sample, using the second laser light.

2. The laser processing device according to claim 1,
wherein the spatial light modulator displays the modulation pattern including a lens pattern that focuses only a portion of the laser light, and generates the second laser light including the portion of the laser light and the first laser light including a remainder of the laser light by modulating the laser light in accordance with the modulation pattern, and
the control unit causes the spatial light modulator to display the modulation pattern, which includes the lens pattern having a focal length calculated based on the focal length of the focusing unit and the set distance, such that the distance between the first focal point and the second focal point becomes the set distance.

3. The laser processing device according to claim 1,
wherein the control unit causes the spatial light modulator to display the modulation pattern generated such that a ratio between an intensity of the first laser light at the first focal point and an intensity of the second laser light at the second focal point becomes a set ratio.

4. The laser processing device according to claim 1,
wherein the control unit causes the spatial light modulator to display the modulation pattern generated based on irradiation conditions of the first laser light and irradiation conditions of the second laser light.

5. The laser processing device according to claim 4,
wherein the irradiation conditions of the second laser light includes a condition under which a beam pattern of the second laser light at the second focal point becomes a top hat shape.

6. The laser processing device according to claim 4,
wherein the irradiation conditions of the second laser light include a condition under which a plurality of the second focal points are formed along the optical axis direction of the second laser light.

7. The laser processing device according to claim 4,
wherein the irradiation conditions of the first laser light include a condition under which a plurality of the first focal points are formed along a direction intersecting the optical axis direction of the first laser light.

8. The laser processing device according to claim 1,
wherein the laser irradiation unit includes a variable attenuator configured to adjust an output of the laser light.

9. The laser processing device according to claim 1,
wherein the laser irradiation unit includes a half-wave plate that is disposed in front of the spatial light modulator, and that controls a polarization direction of the laser light incident on the spatial light modulator.

10. The laser processing device according to claim 1,
wherein a pulse width of the laser light is 1 ps or less.

11. The laser processing device according to claim 1, further comprising:
a distance measurement unit configured to measure a distance between the sample and the transmissive member by detecting light reflected by a laser light incident surface of the sample and light reflected by a surface on the sample side of the transmissive member, and
the control unit acquires the set distance based on the distance measured by the distance measurement unit.

12. A microscope device, comprising:
the laser processing device according to claim 1; and
a microscope unit configured to observe the sample disposed on the disposition unit.

13. A laser processing method using a laser processing device including a disposition unit on which a sample is disposed, a laser output unit configured to output laser light, a laser irradiation unit configured to irradiate the sample, which is disposed on the disposition unit, with the laser light output from the laser output unit, and a transmissive member that is disposed on an optical axis of the laser light between the sample disposed on the disposition unit and the laser irradiation unit, and that transmits the laser light, comprising:
a processing step of performing ablation processing using a first laser light and a second laser light generated from the laser light,
wherein the laser irradiation unit includes
a spatial light modulator configured to display a modulation pattern, and configured to generate the first laser light and the second laser light from the laser light by modulating the laser light in accordance with the modulation pattern and emits the first laser light and the second laser light,
a focusing unit configured to form a first focal point by focusing the first laser light and configured to form a second focal point by focusing the second laser light,
and a control unit configured to control the spatial light modulator,
the processing step includes
a first step of causing the spatial light modulator to display the modulation pattern generated based on a focal length of the focusing unit, such that, by causing the focusing unit to focus the first laser light and the second laser light emitted from the spatial light modulator, the first focal point is located at a first position on the sample side with respect to the transmissive member, the second focal point is located at a second position on the transmissive member side with respect to the first focal point, and a distance between the first focal point and the second focal point in an optical axis direction of the first laser light and the second laser light is set to a set distance, and
a second step of simultaneously performing ablation processing of the sample using the first laser light and ablation processing of particles, which are generated by the ablation processing of the sample, using the second laser light, after the first step.
